(19) United States
(12) Patent Application Publication
(10) Pub. No.: US 2025/0379351 A1
(43) Pub. Date: Dec. 11, 2025

(54) WIDE BAND CIRCUITRY, WITH HIGH DYNAMIC RANGE, TO MEASURE DIELECTRIC CONSTANT AND DIELECTRIC LOSS OF A LOSSY DIELECTRIC MEDIUM SIMULTANEOUSLY

(71) Applicants: King Abdullah University of Science and Technology, Thuwal-Jeddah (SA); Saudi Arabian Oil Company, Dhahran (SA)

(72) Inventors: Muhammad Akram Karimi, Thuwal (SA); Muhammad Arsalan, Dhahran (SA); Atif Shamim, Thuwal (SA)

(73) Assignees: King Abdullah University of Science and Technology, Thuwal-Jeddah (SA); SAUDI ARABIAN OIL COMPANY, Dhahran (SA)

(21) Appl. No.: 18/737,725

(22) Filed: Jun. 7, 2024

(51) Int. Cl. H01P 7/10; H01P 7/04; H03B 5/12; H03B 5/18

(52) U.S. Cl. CPC H01P 7/10; H01P 7/04; H03B 5/1231; H03B 5/1847

(57) ABSTRACT

A system, for measuring a dielectric property of a medium, includes: a resonator; an oscillator electrically coupled to the resonator and configured to generate an electrical signal representing an oscillation of the oscillator when the resonator is disposed in a vicinity of the medium; and measuring circuitry that receives the electrical signal. The measuring circuitry determines, from the electrical signal, at least one of a resonance frequency of the resonator and a quality factor of the resonator. The measuring circuitry determines, from the at least one of the resonance frequency and the quality factor, the dielectric property of the medium.

### BACKGROUND

Measuring dielectric properties of a medium is useful to determine the type of the medium or properties of the medium such as water-cut (WC) or Gas Volume Fraction (GVF). The dielectric properties may be, for example, dielectric constant and dielectric loss of the medium at a certain frequency. The dielectric properties can be measured using, for example, a microwave antenna, a microwave transmission line (TL), or a microwave resonator. A microwave antenna is a radiating component, which can be excited using off-the-shelf (OTS) frequency synthesizers and its radiation power can be measured using OTS power detectors. On the other hand, a microwave TL resonator is typically characterized over a wide frequency band using a vector network analyzer (VNA), which is an expensive piece of equipment and cannot easily be embedded into a compact measuring tool.

### SUMMARY

This summary is provided to introduce a selection of concepts that are further described below in the detailed description. This summary is not intended to identify key or essential features of the claimed subject matter, nor it is intended to be used as an aid in limiting the scope of the claimed subject matter.

This disclosure presents, in accordance with one or more embodiments, a system for measuring a dielectric property of a medium. The system comprises: a resonator; an oscillator electrically coupled to the resonator and configured to generate an electrical signal representing an oscillation of the oscillator when the resonator is disposed in a vicinity of the medium; and measuring circuitry that receives the electrical signal. The measuring circuitry determines, from the electrical signal, at least one of a resonance frequency of the resonator and a quality factor of the resonator. The measuring circuitry determines, from the at least one of the resonance frequency and the quality factor, the dielectric property of the medium. In one or more embodiments, the system includes a wide dynamic range readout circuitry for microwave resonator based sensors.

In another aspect, this disclosure also presents, in accordance with one or more embodiments, a method for measuring a dielectric property of a medium. The method comprises: controlling an oscillator electrically coupled to a resonator to generate an electrical signal representing an oscillation of the oscillator when the resonator is disposed in a vicinity of the medium; receiving, by measuring circuitry, the electrical signal; determining, by the measuring circuitry, from the electrical signal, at least one of a resonance frequency of the resonator and a quality factor of the resonator; and determining, by the measuring circuitry, from the at least one of the resonance frequency and the quality factor, the dielectric property of the medium.

In another aspect, this disclosure also presents, in accordance with one or more embodiments, a non-transitory computer readable medium (CRM) storing instructions for performing an operation that measures a dielectric property of a medium. The operation comprises: controlling an oscillator electrically coupled to a resonator to generate an electrical signal representing an oscillation of the oscillator when the resonator is disposed in a vicinity of the medium; receiving, by measuring circuitry, the electrical signal; determining, by the measuring circuitry, from the electrical signal, at least one of a resonance frequency of the resonator and a quality factor of the resonator; and determining, by the measuring circuitry, from the at least one of the resonance frequency and the quality factor, the dielectric property of the medium.

Other aspects and advantages of the invention will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn are not necessarily intended to convey any information regarding the actual shape of the particular elements and have been solely selected for ease of recognition in the drawing.

FIG. 1 shows a cross-sectional view of a microwave resonating sensor, in accordance with one or more embodiments disclosed herein.

FIG. 2 shows a microwave resonating sensor integrated with oscillator circuitry, in accordance with one or more embodiments disclosed herein.

FIG. 3 shows an example of a circuit configuration of a microwave resonating sensor integrated with the oscillator circuitry, in accordance with one or more embodiments disclosed herein.

FIG. 4A shows a transmission coefficient of a resonator at 100% Water Liquid Ratio (WLR) and 0% Gas Volume Fraction (GVF), in accordance with one or more embodiments disclosed herein.

FIG. 4B shows a transmission coefficient of a resonator at 100% WLR and 50%>GVF>0%, in accordance with one or more embodiments disclosed herein.

FIG. 5A shows a diagram of resonator phase at the resonance frequency (140 MHz in this case) without a coaxial cable, in accordance with one or more embodiments disclosed herein.

FIG. 5B shows a diagram of resonator phase at the resonance frequency (140 MHz in this case) with a 6-inch-long coaxial cable, in accordance with one or more embodiments disclosed herein.

FIG. 6A shows resonator loss, in accordance with one or more embodiments disclosed herein.

FIG. 6B shows oscillator core's amplifier gain, in accordance with one or more embodiments disclosed herein.

FIG. 7 shows resonator phase and simulated inverted oscillator phase, where the intersection frequency point between the two types of phases (134.4 MHz and 140.6 MHz in this case) satisfies phase condition for sustained oscillation, in accordance with one or more embodiments disclosed herein.

FIG. 8 shows a prototype microwave resonating sensor, in accordance with one or more embodiments disclosed herein.

FIG. 9 shows a test setup, in accordance with one or more embodiments disclosed herein.

FIG. 10 shows intersection of resonator phase at different water levels with measured inverted phase of the oscillator, in accordance with one or more embodiments disclosed herein.

FIG. 11 shows comparison of resonance frequency of the resonator with oscillation frequency of the oscillator and phase meeting points at different water levels, in accordance with one or more embodiments disclosed herein.

FIG. 12 shows intersection of resonator phase for different water levels with inverted phase of the oscillator, in accordance with one or more embodiments disclosed herein.

FIG. 13 shows comparison of resonance frequency of the resonator at different water levels with oscillation frequency of the oscillator, in accordance with one or more embodiments disclosed herein.

FIG. 14 shows a transient response of the oscillator, in accordance with one or more embodiments disclosed herein.

FIG. 15 shows a diagram demonstrating gain gap, in accordance with one or more embodiments disclosed herein.

FIG. 16A shows quality factor of a resonator under varying water-cut (WC) and gas volume fraction (GVF) conditions, in accordance with one or more embodiments disclosed herein.

FIG. 16B shows oscillation power of the oscillator that is coupled to the resonator under WC and GVF conditions, in accordance with one or more embodiments disclosed herein.

FIGS. 17A and 17B respectively show oscillator core gain before and after optimization, in accordance with one or more embodiments disclosed herein.

FIG. 18A shows quality factor of the resonator, in accordance with one or more embodiments disclosed herein.

FIG. 18B shows oscillator power when the oscillator is coupled to the resonator, in accordance with one or more embodiments disclosed herein.

FIG. 19 shows gain of the oscillator at different base voltages, in accordance with one or more embodiments disclosed herein.

FIG. 20A shows the quality factor of the resonator in relation with GVF and WC at 3% water salinity, in accordance with one or more embodiments disclosed herein.

FIG. 20B shows the base voltage of the oscillator in relation with GVF and WC at 3% water salinity, in accordance with one or more embodiments disclosed herein.

FIG. 21A shows the quality factor of the resonator in relation with GVF and WC at 13% water salinity, in accordance with one or more embodiments disclosed herein.

FIG. 21B shows the base voltage of the oscillator in relation with GVF and WC at 13% water salinity, in accordance with one or more embodiments disclosed herein.

FIG. 22 shows a block diagram of embedded control for dynamic gain adjustment, in accordance with one or more embodiments disclosed herein.

FIG. 23 shows a block diagram for broad frequency band coverage of a readout circuitry, using RF switches, in accordance with one or more embodiments disclosed herein.

FIG. 24A shows a block diagram of Architecture 1 of a system, in accordance with one or more embodiments disclosed herein.

FIG. 24B shows a block diagram of Architecture 2 of a system, in accordance with one or more embodiments disclosed herein.

FIG. 25 shows a diagram of a method for measuring dielectric properties of a medium, for example simultaneously measuring dielectric constant and dielectric losses, in accordance with one or more embodiments disclosed herein.

FIG. 26 shows a computer system, in accordance with one or more embodiments disclosed herein.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the disclosure, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements. In addition, throughout the disclosure, “or” is interpreted as “and/or,” unless stated otherwise.

One or more embodiments disclosed herein describe an approach to extract dielectric properties of a medium using readout circuitry. Output parameters of the readout circuitry, such as voltage or current, provide one-to-one relationship with a microwave resonator resonance frequency (fo) and quality (Q) factor. After measuring the resonance frequency and Q factor of the resonator, the dielectric properties of the medium may be extracted using one-to-one relationships between the resonance frequency and Q factor and the dielectric properties of the medium. For example, the dielectric constant of the medium at high frequencies (e.g., microwave frequencies) can be determined based on the resonator resonance frequencies, and the dielectric losses of the medium can be determined based on the resonator Q factor. Determining dielectric properties of the medium is useful, for example, to determine the type or other characteristics of the medium. These embodiments are described below in detail.

The measuring circuitry can be calibrated based on the one-to-one correspondences such that the output of the measuring circuitry can show the resonance frequency and Q factor of the resonator as well as the dielectric properties of the medium. For example, the resonance frequency and Q factor of the resonator can be once determined using a vector network analyzer (VNA) and once using the measuring circuitry according to one or more embodiments. Then, the output of the measuring circuitry can be calibrated to the values of the resonance frequency and Q factor shown on the VNA. For example, the output of the measuring circuitry can correspond to the output of the VNA in a table, and later on the table may be used to find the resonance frequency and Q factor based on the output of the measuring circuitry.

Measuring dielectric properties of a medium is useful to determine the type of the medium or other properties of the medium such as water-cut (WC) or Gas Volume Fraction (GVF). The dielectric properties may be, for example, dielectric constant and dielectric loss of the medium at a certain frequency for example in the microwave regime.

Dielectric based electrical sensors are common in several industries including oil and gas. For example, more than 50% of multiphase flow meters (MPFMs), used for upstream production optimization, employ a dielectric sensing mechanism. Depending on the excitation frequency, dielectric sensing mechanism can be broadly divided into two categories: low frequency dielectric sensing using capacitors or conductors; and high frequency microwave dielectric sensing using antennas or resonators. The readout circuitries for low frequency capacitance/conductance measurements are widely available and can perform a single point measurement as fast as in few micro-seconds. However, the readout circuitries for high frequency microwave sensors are not only expensive but are also generally slow. This becomes more prominent in the case of microwave resonators that scan a range of frequencies to accurately find the variable resonating frequency of the sensor. This scanning process takes significant time that increases proportionally with higher sensitivity and accuracy of the sensor. Accordingly, despite offering significant sensing advantages, conventional microwave sensors lack versatile readout options and therefore their use is relatively limited as compared to low frequency dielectric sensors.

According to one or more embodiments, the dielectric properties of the medium at high frequencies (e.g., microwave frequencies) can be measured using, for example, a resonator. The resonator may be a microwave resonator. For example, in one or more embodiments, the resonator may be a T-resonator or a modified version of a T-resonator. While the resonator can be used for the measurement over a wide frequency band, conventionally a VNA is used to read the resonator output. VNA, however, is an expensive piece of equipment and cannot easily be embedded into a compact product. Accordingly, one or more embodiments of the present application disclose a low cost, compact, and light weight readout circuitry to measure dielectric properties of a medium using a microwave resonator.

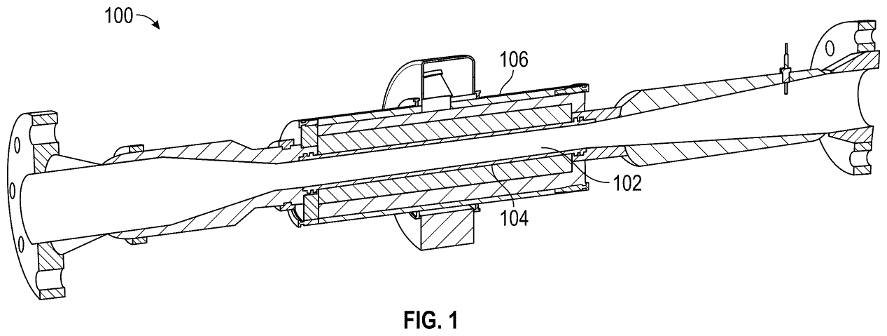

Some resonators can be formed using a special arrangement of TL, such as a T-resonator. When a resonator is disposed in vicinity of a medium, the impedance of the resonator will be affected by the dielectric properties of the medium, in microwave frequencies. The resonator is disposed in the vicinity of the medium such that the electromagnetic (EM) fields of the resonator enter the medium and change the resonance frequency of the resonator by a detectable fraction. For example, the resonator may be disposed in or on the medium, may contain the medium, or may be disposed adjacent to the medium without contacting the medium, depending on measurement sensitivity, situation, or other factors. A simple piece of microwave transmission line can be converted into a resonator if it is shunted with an open-ended or short-ended stub. Put differently, in an example, the resonator may include a transmission line coupled with an oscillator and also a shunt stub that is either open-ended or short ended. FIG. 1 shows a cross-sectional view of an example of the complete system (100) including a microwave resonator (104) in vicinity of a medium (102). The resonator (104) is connected to a readout circuitry (106) for determining resonance properties of the resonator (104). In one or more embodiments, the resonance properties of the resonator (104) may be resonance frequency and Q factor of the resonator. While the embodiments disclosed herein are described with reference to the described resonator, the invention is not limited to a particular type of resonator and other resonator types may be used depending on a specific use or application.

One or more embodiments disclose using a resonator, which combines characteristics of a TL and of a resonator, to measure the dielectric properties of the medium. Resonators have been used for detection of WC for application in upstream production monitoring and optimization. However, resonators have been characterized using a typical VNA, which is not only expensive but also provides slow measurements. For example, characterizing a resonator using a VNA can be as slow as 6 to 7 measurements per second.

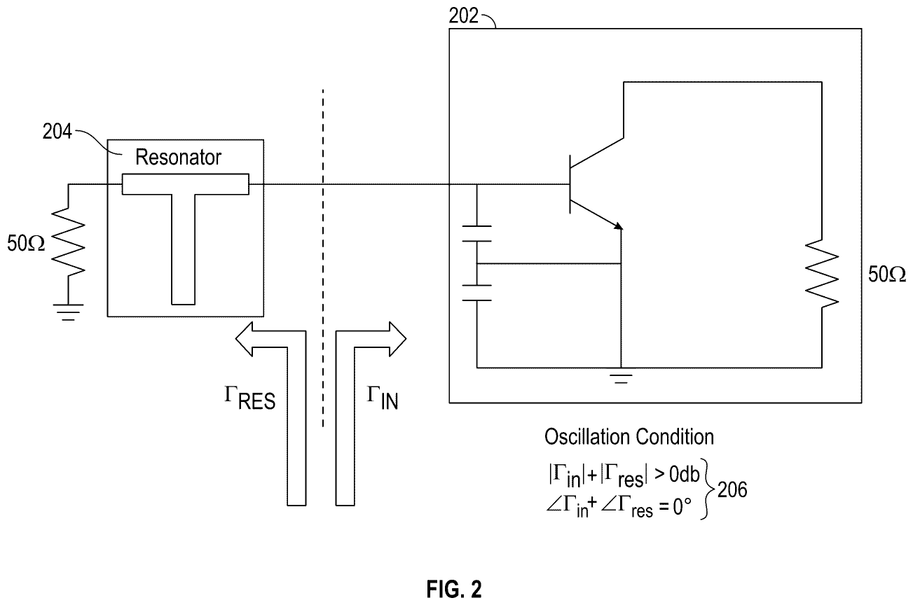

A resonator reflects most of the microwave power injected to the resonator at its resonance frequency, while some of the injected power is absorbed by the resonator and does not reflect. In one or more embodiments, the reflection properties of the resonator is investigated by integrating the resonator with a microwave oscillator core (hereinafter will be referred to as “oscillator”). In one or more embodiments, the resonator and oscillator may, for example, be integrated in a Colpitt configuration, as shown in FIG. 2. Specifically, FIG. 2 shows part of a readout system (200) for measuring dielectric properties of the medium at microwave frequencies. The system (200) includes an oscillator (202) and a resonator (204) that are integrated with one another in a Colpitt configuration or one of its derivatives, which may work better for high bandwidth applications. In one or more embodiments, the oscillator is included in a readout circuitry and is used to measure the resonance frequency and Q factor the resonator. Specifically, the readout circuitry may include the oscillator and measuring circuitry that measures a signal of the oscillator to determine the resonance frequency and Q factor of the resonator.

As shown in FIG. 2, there may be two oscillation conditions (206), amplitude condition and phase condition, that must be met at the interface of the resonator (204) and oscillator (202). While most of the injected microwave power into the resonator (204) is reflected at the resonance frequency, some power is absorbed in the resonator (204) due to the dielectric losses. Therefore, the oscillator (202) must compensate for the absorbed power (losses) by providing enough gain at the resonance frequency. The sufficient gain requirement at the resonance frequency is known as gain condition and is represented as |Γin|+|Γres|>0 dB. |Γin| is the power of the injected signal from the oscillator (202) and |Γres| is the power of the reflected signal from the resonator (204). Additionally, the reflected signal from the resonator (204) and the injected signal from the oscillator (202) must constructively interfere in order to sustain the oscillation. This requirement is commonly known as phase condition and is represented as ∠Γin+∠Γres=0°. Here, ∠Γin is the phase of the injected signal from the oscillator (202) and ∠Γres is the phase of the reflected signal from the resonator (204).

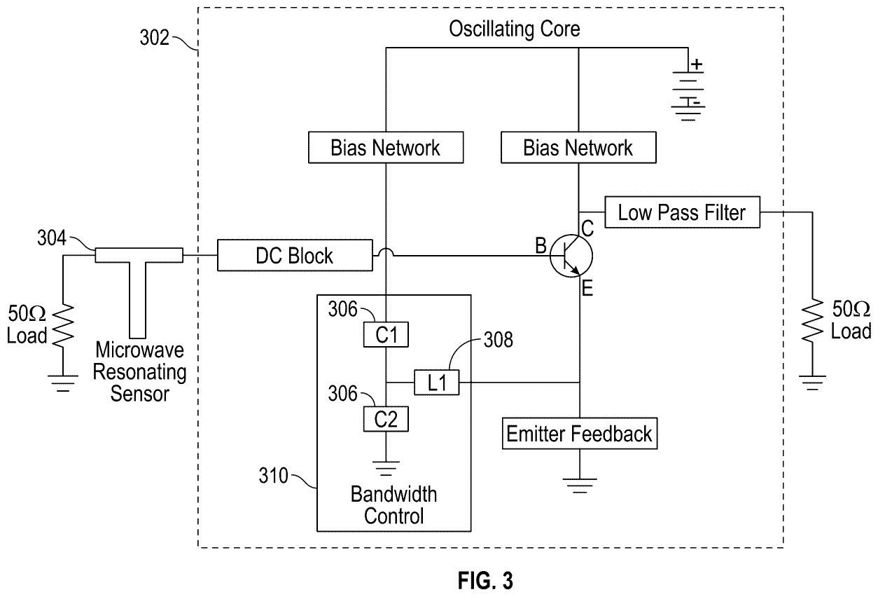

FIG. 3 shows, according to one or more embodiments, a derivation of a standard system configuration. The system shown in FIG. 3 includes an oscillator (302) and a resonator (304). The system of FIG. 3 is for wide band microwave readout and can operate in a water-continuous multiphase region. The values of the two capacitors C1 and C2 (306) and of the load L1 (e.g., a resistor) (308), which are included in the bandwidth control section (310), can determine the operating range of the oscillator (302). The technique used for extending the bandwidth is by flattening the phase of the oscillator with respect to frequency over the desired bandwidth. In one or more embodiments, the phase response of the oscillator may be intended to be flat with respect to frequency but in practical implementations, it may be difficult to achieve this. That is why alternatively it may be considered to flatten the phase response as much as possible with the updated architecture and appropriate use of C1,C2, and L1 values.

One or more embodiments described herein disclose measurement of the resonance frequency of the resonator using a readout circuitry. In designing a readout circuitry for a resonator, limited bandwidth of the readout circuitry may be challenging and various techniques may be employed to achieve a maximum possible bandwidth for the readout circuitry. The wide-band readout circuitry according to one or more embodiments may have an operating bandwidth that matches the resonating bandwidth of the resonator.

According to one or more embodiments, the resonator resonance was investigated in the following operating conditions:
Condition 1—100% Water Liquid Ratio (WLR) and 0% GVF (i.e., the resonator is fully filled with water); and
Condition 2—100% WLR and 50%>GVF>0% (i.e., the resonator is filled with water and air)

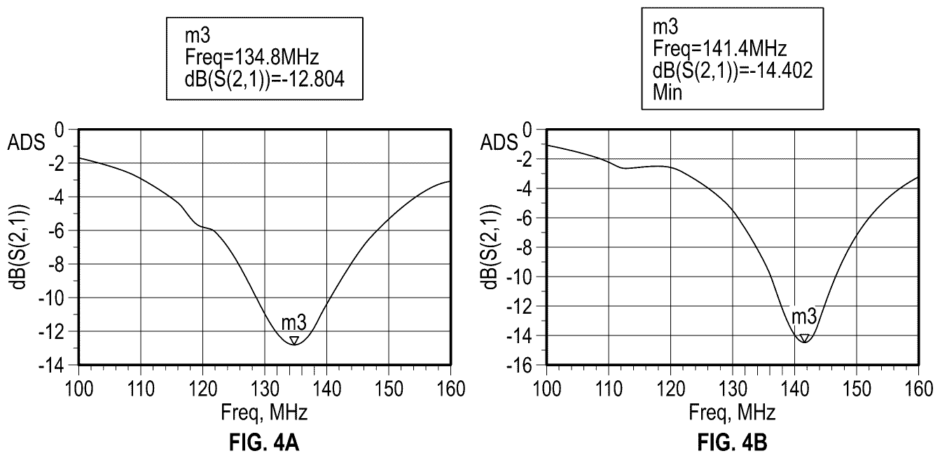

FIGS. 4A and 4B show transmission coefficient responses of the resonator for aforementioned Conditions 1 and 2, respectively. Specifically, FIGS. 4A and 4B show that between Conditions 1 and 2, the resonance frequency of the resonator ranges from 134.8 MHz to 141.4 MHz as an example. However, the proposed architecture can be utilized for much higher bandwidths as well. For the given example, the oscillator must be optimized to give sufficient gain (to compensate for the resonator losses) and appropriate phase (to constructively interfere with the reflecting signal from the resonator) over the aforementioned frequency range.

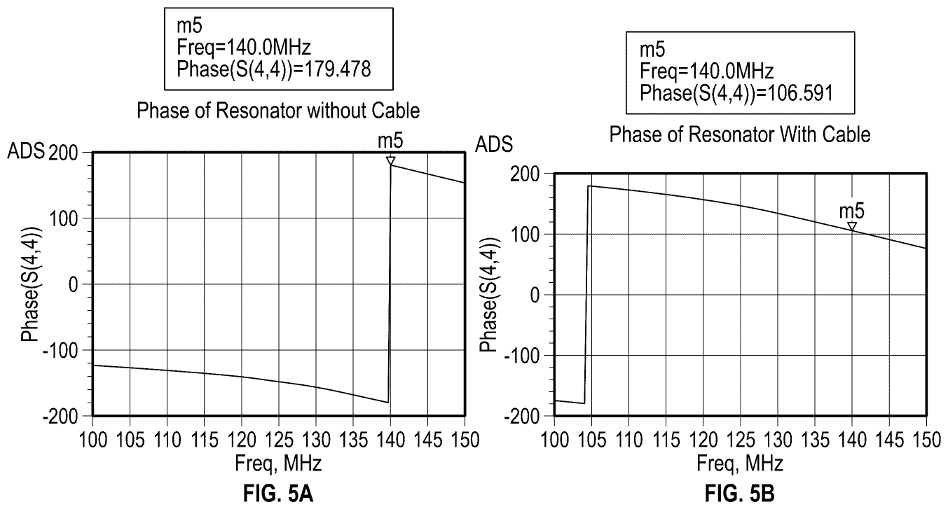

According to one or more embodiments, the resonator may be connected to the oscillator via a coaxial cable, which may be a Radio Frequency (RF) cable. A low loss coaxial cable may not add significant loss to the signal communication between the oscillator and resonator, but it may affect the phase significantly depending on the length of the coaxial cable. Accordingly, the effect of a 6-inch-long (15.24 centimeter (cm)) coaxial cable is investigated herein. FIGS. 5A and 5B show the phase output of the resonator resonating at ˜140 MHz (m5) without and with the 6-inch-long coaxial cable, respectively. According to FIGS. 5A and 5B, the 6-inch-long coaxial cable contributes to almost 74° phase at the resonance frequency of 140 MHz. Considering this phase shift, the phase response of the oscillator was optimized accordingly to meet the phase requirement described above with reference to FIG. 2. In addition, the oscillator was optimized to provide sufficient gain to meet the sufficient gain requirement described above with reference to FIG. 2.

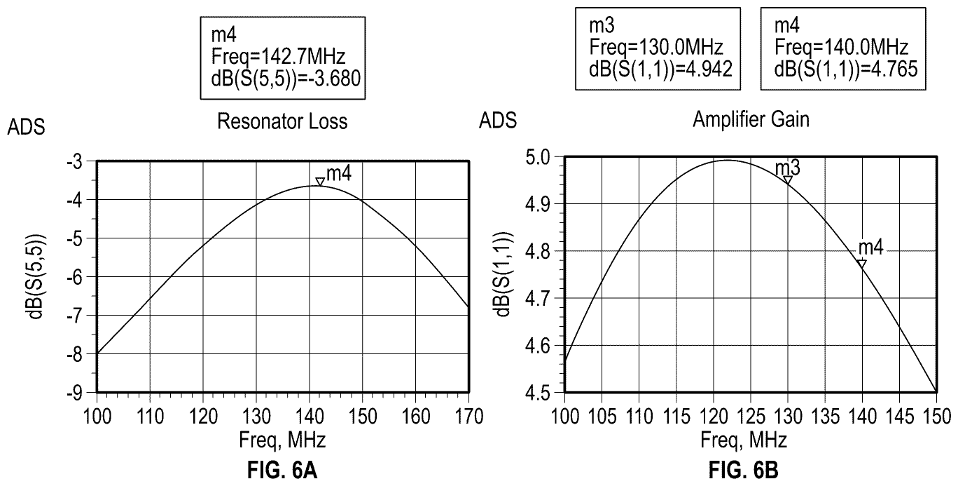

FIG. 6A shows the resonator loss and FIG. 6B shows the oscillator gain. The resonator loss and oscillator gain complement each other for a sustained oscillation. Similarly, the phase of the oscillator was adjusted such that an inverted value of the oscillator phase meets (matches) the phase of the resonator combined with the coaxial cable at the resonance frequency. As shown in FIGS. 6A and 6B, the loss of the resonator peaks at almost 3.7 dB at the resonance (peak) frequency of 140 MHz (m4), while the oscillator is able to give a gain of almost 4.7 dB at the same frequency of 140 MHz (m4). Further, the oscillator gain is optimized in a wide range from 130 MHz (m3) to 140 MHz (m4) to have sufficient gain for the resonator in this range. Depending on the environmental condition of the resonator (i.e., the resonator being in vicinity of a specific medium), the resonance frequency of the resonator changes. Accordingly, the oscillator is optimized to provide sufficient gain in a wide frequency range. Therefore, the oscillator gain is sufficient to compensate the resonator loss to maintain a sustainable oscillation.

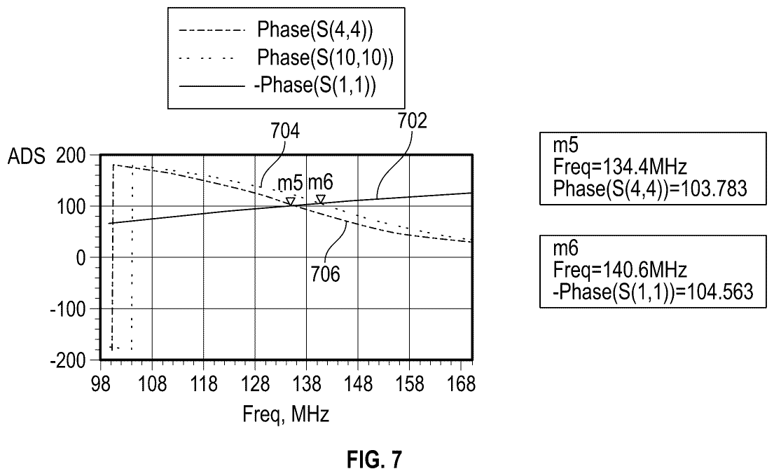

FIG. 7 shows resonator phase and simulated oscillator phase, complementing each other for a sustained oscillation. The two curves corresponding to the resonator phase S(4,4) (706) and S(10,10) (704) show the frequency extremes under varying WLR and GVF conditions 1 (m5) and 2 (m6) described above. In FIG. 7, S(4,4) (706) presents the phase of the resonator including the coaxial cable in Condition 1, S(10,10) (704) presents the phase of the resonator including the coaxial cable in Condition 2, and S(1,1) (702) presents the inverted phase of the oscillator. The intersection point between the inverted phase of the oscillator (702) and the phases of the resonator (704, 706) are where the phase condition meets and therefore represent the expected oscillation frequencies of the oscillator. These intersection frequency points are designed to be as close to the resonator resonance frequency as possible. In FIG. 7, the intersection frequencies of m5 (134.4 MHz) and m6 (140.6 MHz) are close to the resonator resonance frequencies of 134.8 MHz and 141.4 MHz described above in Conditions 1 and 2 with respect to FIGS. 4A and 4B.

According to one or more embodiments, a flatter inverted oscillator phase increases the sensitivity of detection of the intersection frequencies (i.e., reduces compression of the intersection frequency points). The sensitivity of the detection can be defined as changes in the intersection frequency based on a change in the water level or GVF. Accordingly, the higher the slope of the inverted oscillator' phase in FIG. 7, the less sensitivity of detection of the resonator phase.

In one or more embodiments, the resonance frequency was changed by changing the water level. Specifically, the tube was filled with different water levels while the rest of the tube contains gas or (air). Accordingly, changing the water level, in turn, changes the GVF in an inverse relation; more water level means lower value of GVF.

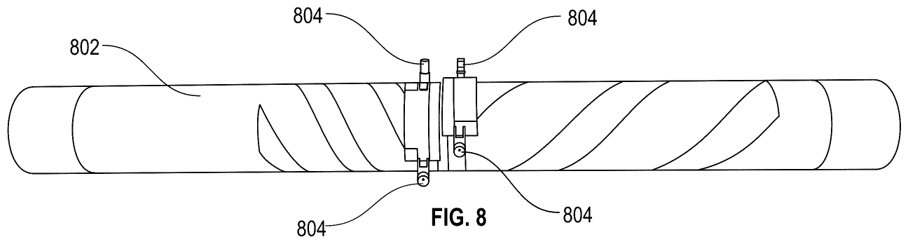

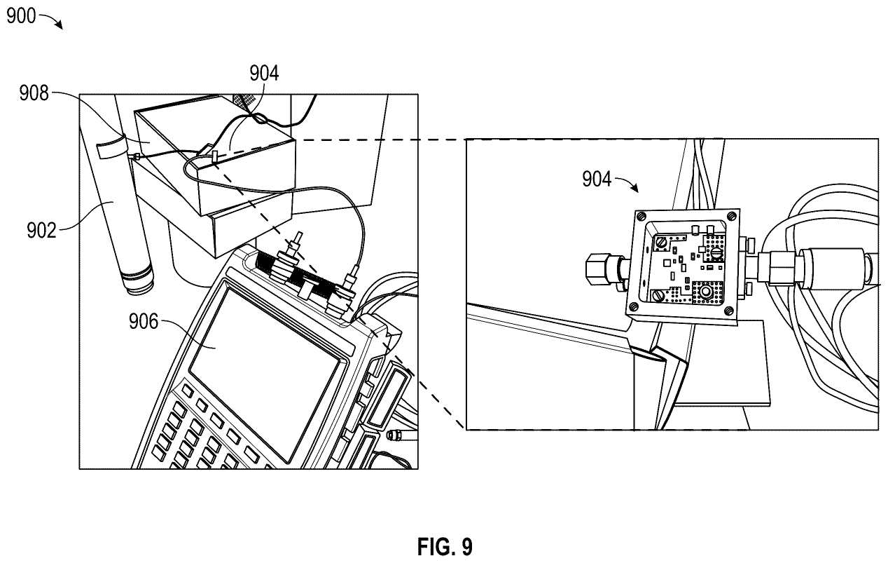

FIG. 8 shows a prototype of a microwave Dual Mutually Orthogonal Resonance DMOR resonator (hereinafter, will be referred to as DMOR) as a testbench. The DMOR is a hollow tube (802) that includes a resonator and electrical connections (804) for measuring the output of the resonator. As shown in FIG. 9, to measure resonance frequencies of the resonator of the DMOR, the DMOR (902), which is similar to the DMOR shown in FIG. 8, is connected to an oscillator (904) and to a conventional VNA (906). The DMOR (902) is connected to the oscillator (904) through a 6-inch-long coaxial cable (908). The oscillator was tuned in the range of 130 MHz-140 MHz and the tube of the DMOR (902) was filled with different water levels, which has an inverse relation with the GVF, to achieve a range of resonance frequencies for the resonator embedded in the DMOR (902). The resonance frequencies of the resonator were then measured through the VNA (906). The resonance frequencies of the resonator were also measured by measuring phase and oscillation frequencies of the oscillator (904) to compare the results with the results measured via the VNA (906).

In one or more embodiments, some numbers about the aforementioned experiment are as follows:
resonance frequency in air Measured on VNA is 220.25 MHz;
water used had a salinity concentration of 3% (30,000 ppm);
the resonance frequency (fo) with the tube fully filled with water was measured on VNA as 134.5 MHz; and
when varying water relative to air in tube (varying GVF), the resonance frequency (fo) varied in the range of 134.5 MHz-141 MHz. The lowest water level corresponds to the highest GVF and the highest water level corresponds to the lowest GVF.

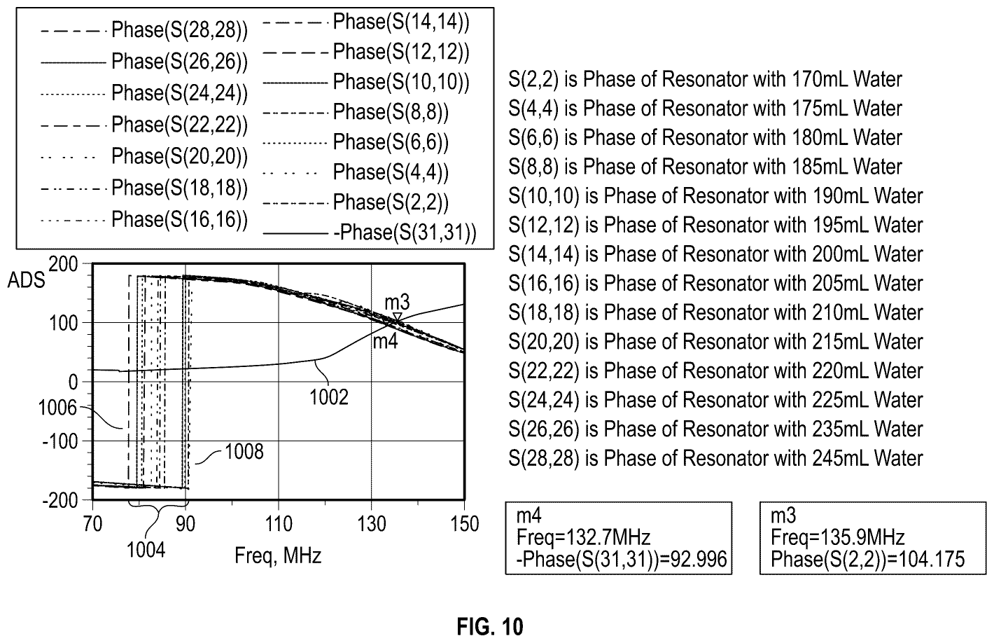

According to one or more embodiments, to do the experiment the tube was initially filled with water to a level where the resonance frequency (fo) was 141 MHz. Then, water was incrementally added to the tube to lower the resonance frequency (fo) until the tube was completely filled with water at the resonance frequency if 134.5 MHz. FIG. 10 shows the intersections of resonator phases (1004) with the inverted phase of the oscillator (1002) at different water levels. The inverted phase of the oscillator (1002) may be measured via VNA that measures the S-parameters of the oscillator. On the other hand, the resonator phases (1004) may also be measured via the VNA. To this end, the water level gradually increases from 170 milliliter (mL) corresponding to S(2,2) (1008) to 245 mL corresponding to S(28,28) (1006) with 5 mL increments. According to one or more embodiments, the intersection points correspond to (i.e., have one-to-one relation with) the resonance frequencies of the resonator at the water levels. In FIG. 10, S(31,31) (1002) represents the inverted phase of the oscillator and S(2,2) to S(28,28) (1004) represent the phases of the resonator at different water levels with the increments described above. In FIG. 10, the phase intersections for the lowest water level S(2,2) (1008) and the highest water level S(28,28) (1006) water level are annotated as m3 and m4, respectively. The intersection points represent the phase meeting condition and also correspond to the expected oscillation frequency of the oscillator. As shown in FIG. 10, the oscillation frequency of the oscillator varies in the range of 132.7 MHz (m4) corresponding to the highest water level to 135.9 MHz (m3) corresponding to the lowest water level. The measured phase meeting points (i.e., phase intersection points) are good approximations of the oscillation frequencies with a small offset from one another.

Comparing FIG. 10 (which is an experimental result) with FIG. 7 (which is a simulation result), the range of the oscillation frequency is slightly less in FIG. 10 than the simulated phase meeting points shown in FIG. 7. This is because of higher phase angle slope of the inverted phase of the oscillator (1002) in FIG. 10 (than in FIG. 7), which results in more compression of the measured oscillation frequencies of the oscillator.

It is evident from FIG. 10 that the oscillation frequency of the oscillator may not exactly match the resonance frequency of the resonator and that there may be some compression as well as some offset between the two frequencies. However, the offset and compression may require the oscillator readout to be calibrated in its operating frequency range. This calibration may be combined with the calibration of the intended device such as multiphase flow meter or WC meter.

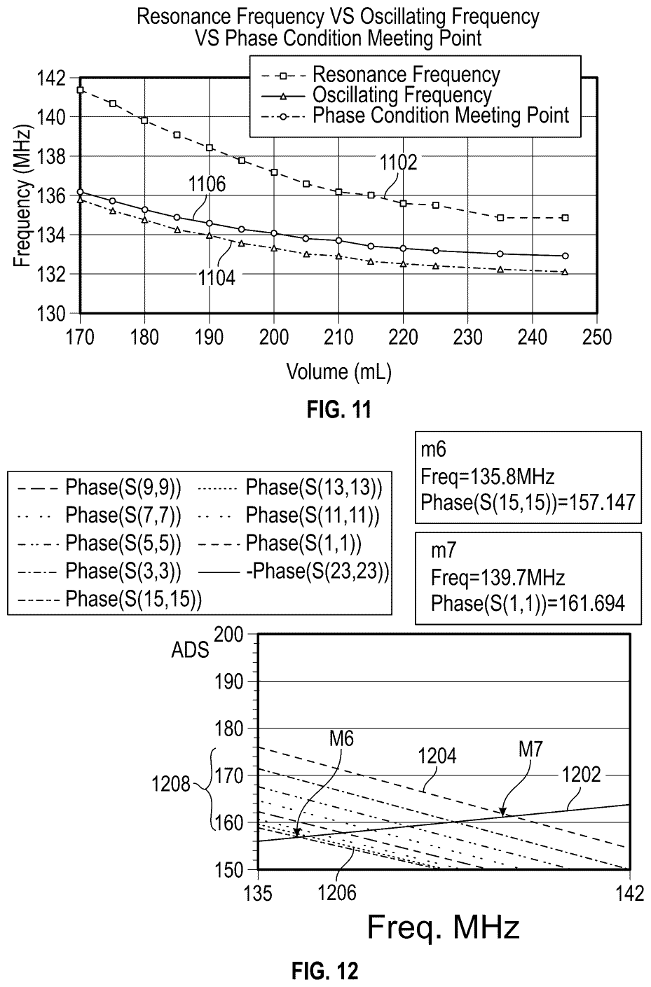

FIG. 11 shows comparison between the resonance frequencies of the resonator (1102) (measured via the VNA), the oscillation frequencies of the oscillator (1104) measured using the spectrum analyzer when the oscillator is connected to and powers the resonator, and the phase condition meeting points between the oscillator and the resonator (1106) (including the 6-inch-long coaxial cable) measured using the measuring circuitry in relation to the water level (volume) in the tube. As shown in FIG. 11, there is one-to-one correspondence between the oscillation frequency of the oscillator (1104) and the resonance frequency of the resonator (1102). Therefore, the measuring circuitry can estimate the resonance frequency of the resonator (1102) by measuring the oscillation frequency of the oscillator (1104) and using the one-to-one correspondence between the resonance frequency and the oscillation frequency. For example, the measuring circuitry that measures the oscillation frequency of the oscillator (1104) can determine the resonance frequency of the resonator (1102) based on a table that includes the one-to-one correspondence.

Similarly, the measuring circuitry can determine the resonance frequency of the resonator (1102) by measuring the phase condition meeting point (1106) and using the one-to-one correspondence between the resonance frequency (1102) and the phase condition meeting point (1106).

FIG. 11 shows that sensitivity of the oscillation frequency of the oscillator (1104) (i.e., changes in the oscillation frequency for a change in the water level) may be slightly less than sensitivity of the measured resonance frequency of the resonator (1102) (i.e., changes in the resonance frequency for a change in the water level). This is because of the higher slope of the measured inverted phase of the oscillator. The measured sensitivity of the oscillation frequency of the oscillator is estimated to be 2.7%.

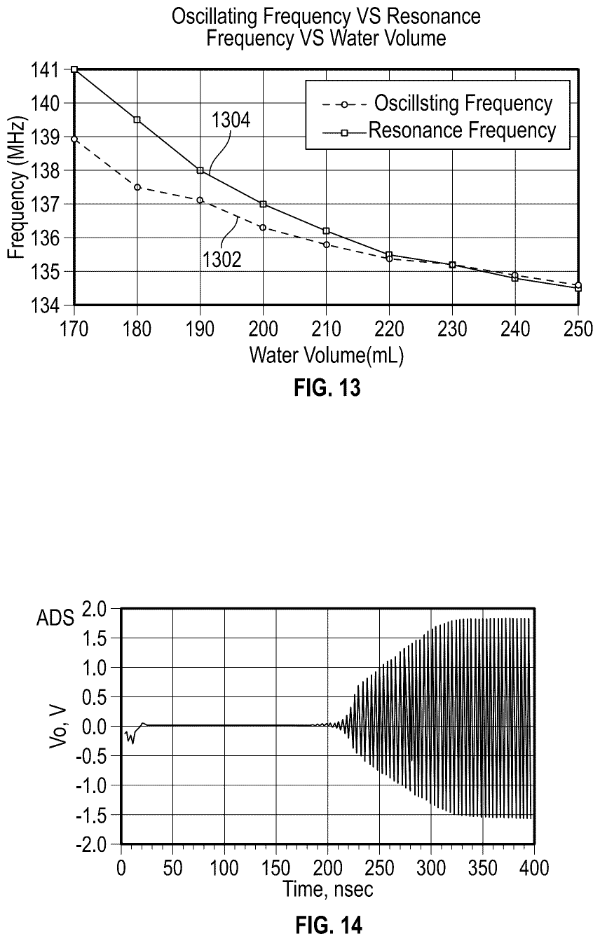

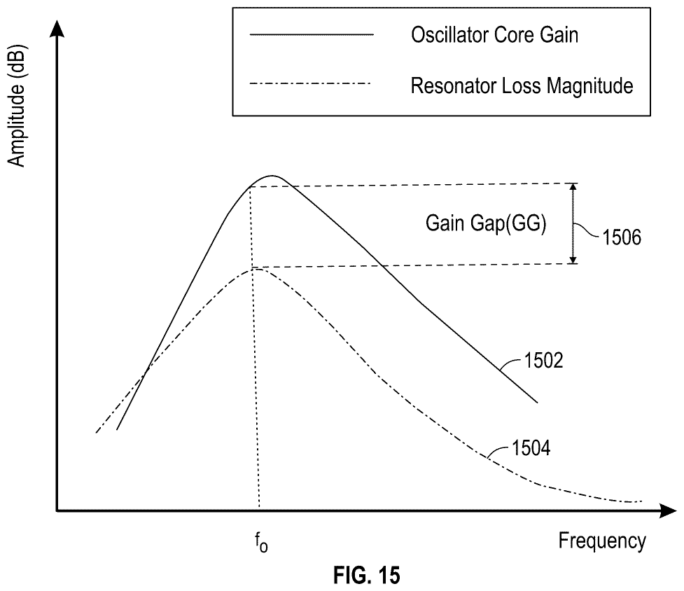

The measurements discussed above with reference to FIGS. 9-11 are performed while the 6-inch-long coaxial cable connected the resonator of the DMOR to the oscillator, as shown in FIG. 9. In one or more embodiments, the effect of the 6-inch-long coaxial cable is described herein with reference to FIGS. 12 and 13, where the 6-inch-long coaxial cable is removed such that the oscillator is directly connected to the resonator. As described above, longer length of the coaxial cable in the path between the resonator and oscillator can result in higher slope of the inverted phase of the oscillator. Therefore, some of the slope of the inverted phase of the oscillator shown in FIG. 10 is due to existence of the 6-inch-long coaxial cable. As described above, the higher the slope, the more the compression and the less the sensitivity of the oscillation frequency or phase meeting point. Accordingly, one way to increase the sensitivity is to reduce the length of the coaxial cable, for example removing it entirely. FIG. 12 shows the phase meeting points (intersections between the resonator phases and the inverted oscillator phase) for the case where the resonator is directly connected to the oscillator without the coaxial cable. In FIG. 12, S(23,23) (1202) represents the inverted phase of the oscillator and S(1,1) to S(15,15) (1208) represent the phases of the resonator at different water levels. In FIG. 12, the phase intersections for the lowest and highest water levels are annotated as m7 and m6, respectively, which correspond to the phases of the resonator S(1,1) (1204) and S(15,15) (1206). Comparing the expected oscillation frequency range extracted from FIG. 12 with that from FIG. 10, the oscillator sensitivity is increased from ˜2.5% (in FIGS. 10) to ˜4% (in FIG. 12).

FIG. 13 shows comparison between the measured oscillation frequency of the oscillator (1302) (measured via the measuring circuitry connected to the oscillator) and the resonance frequency of the resonator (1304) measured using the VNA, for the scenario where the oscillator is directly connected to the resonator without a coaxial cable. FIG. 13 shows a sensitivity of ˜3.1%, which is higher than the sensitivity of 2.7% described above with reference to FIG. 11. In addition, the offset between the oscillation frequency of the oscillator (1302) and the resonance frequency of the resonator (1304) is decreased in FIG. 13 compared with the offset shown in FIG. 11.

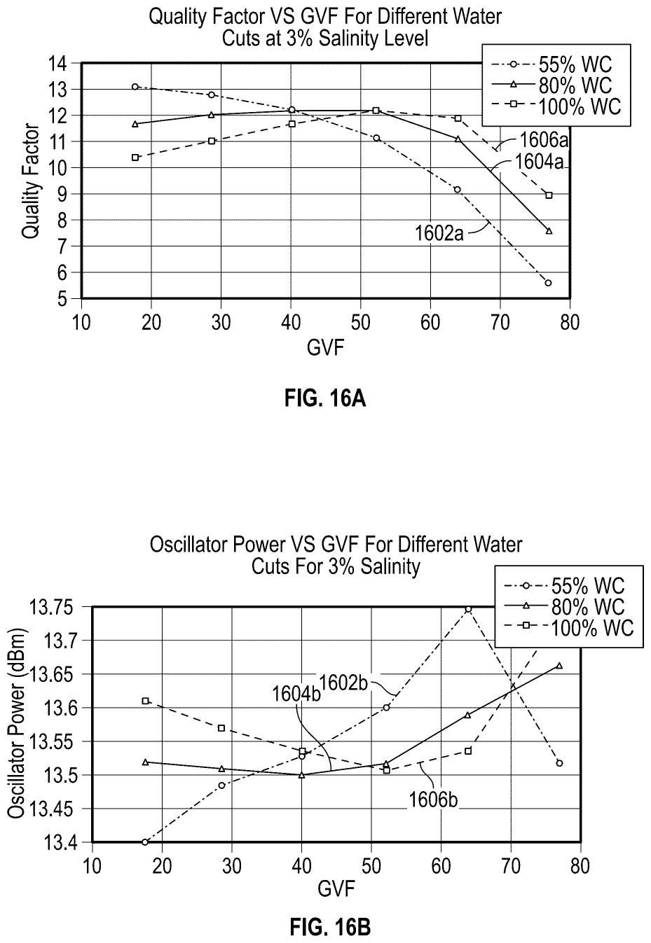

The readout circuitry according to one or more embodiments is faster in measurement than a conventional VNA. FIG. 14 shows a transient response of the oscillator when the oscillator starts to generate an electrical signal at the oscillation frequency. In this example, the oscillator takes between 400-500 nanosecond to give a stable oscillation output. Considering this with other delays in the signal path for measuring the oscillation frequency of the oscillator, one measurement of the dielectric constant of the medium may be done in less than 0.5 millisecond. Therefore, a measurement speed of approximately 2000 Hz may be achieved. Such a fast measurement may be helpful in correlating the output of multiple resonators with gas or liquid flow rates.

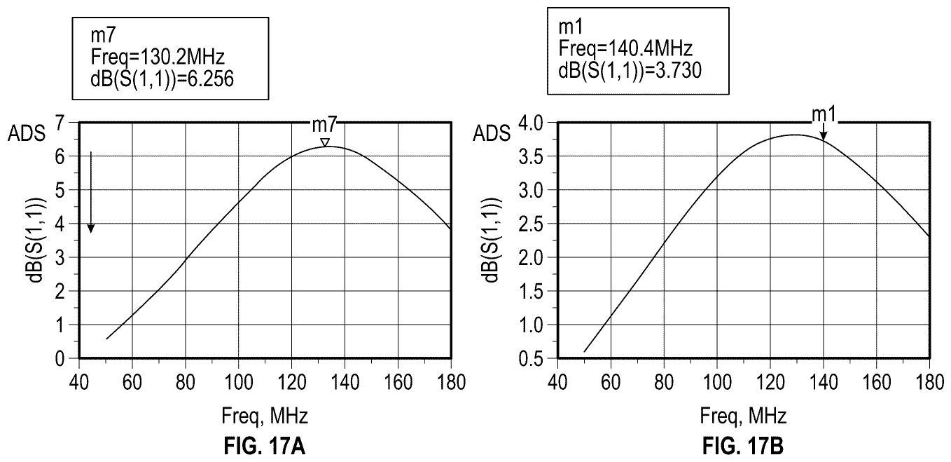

FIG. 15 shows amplitudes of the oscillator gain (1502) and resonator loss (1504) as functions of frequency. The difference in the amplitudes of the oscillator gain (1502) and resonator loss (1504) is referred to as gain gap (GG) (1506). According to FIG. 15, the gain gap (1506) decreases when the resonator loss (1504) increases. Because the oscillation power of the oscillator is proportional to the gain gap (1506), the oscillation power of the oscillator is an inverse function of the resonator loss. One way to measure the dielectric losses of the medium in the dielectric measurement is to measure the quality factor (Q factor) of the resonator, which has an inverse relationship with the dielectric losses of the medium. Accordingly, the relationship between the Q factor of the resonator and the oscillation power of the oscillator is investigated herein, in accordance with one or more embodiments.

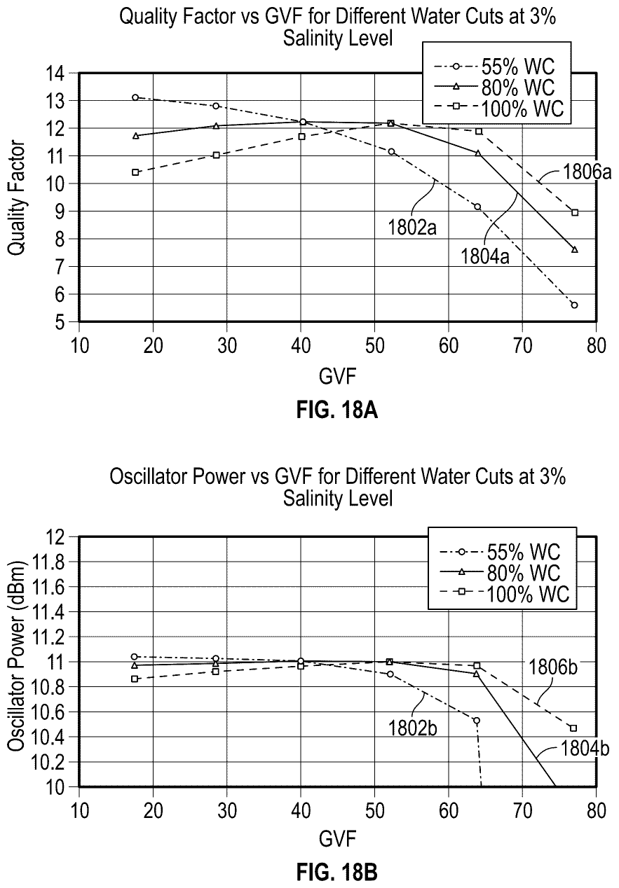

In one or more embodiments, the relationship between the resonator Q factor and the oscillation power of the oscillator was investigated in a situation where the oscillator is saturated and in a situation where the oscillator is not saturated. The difference between the saturated and unsaturated conditions of the oscillator is that the variation in the output oscillation power of the oscillator when the oscillator is saturated is considerably smaller than the variation of the output oscillation power of the oscillator when the oscillator is unsaturated. FIGS. 16A and 16B show the results for the situation where the oscillator is saturated. FIGS. 16A and 16B show the Q factor of the resonator and the oscillation power of the oscillator, respectively, in relation with different WCs and different GVFs. Specifically, FIG. 16A shows the Q factor for WCs of 55% (1602a), 80% (1604a), and 100% (1606a). Similarly, FIG. 16B shows the oscillation power for WCs of 55% (1602b), 80% (1604b), and 100% (1606b). According to FIGS. 16A and 16B, in the saturation situation, there is no direct relationship between the Q factor of resonator and the oscillation power of the oscillator. When the oscillator is saturated, because variation of its power is small, the resonator loss does not correspond well with the oscillation power of the oscillator.

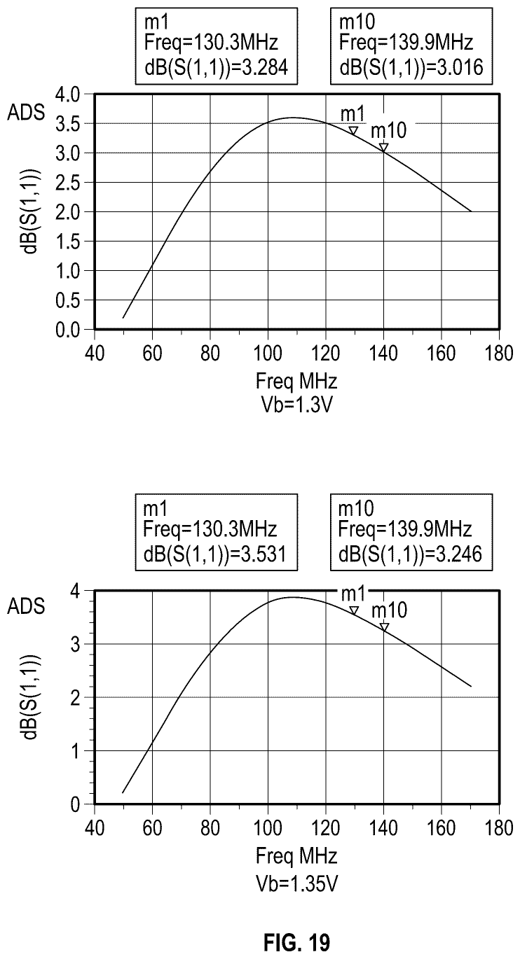

Then the relation between the Q factor of resonator and the oscillation power of the oscillator was investigated for the situation where the oscillator is unsaturated. To this end, to insure that the oscillator operates without saturation, the oscillator gain was reduced (optimized) from 6.2 dB to 3.7 dB as shown by points m7 and m1 in FIGS. 17A and 17B.

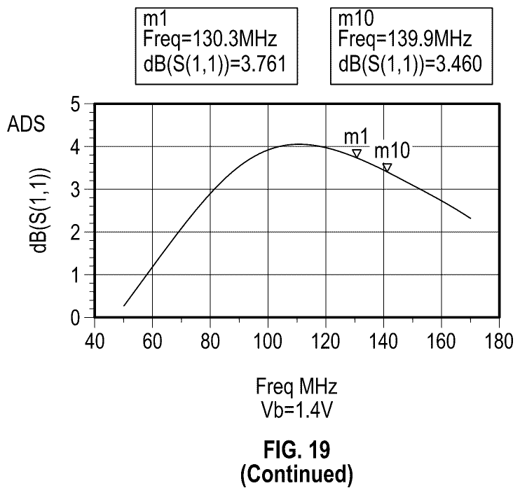

FIGS. 18A and 18B show the results for the situation where the oscillator is unsaturated. FIGS. 18A and 18B show the Q factor of the resonator and the oscillation power of the oscillator, respectively, in relation with different WCs and different GVFs. Specifically, FIG. 18A shows the Q factor for WCs of 55% (1802a), 80% (1804a), and 100% (1806a). Similarly, FIG. 18B shows the oscillation power for WCs of 55% (1802b), 80% (1804b), and 100% (1806b). According to FIGS. 18A and 18B, in the unsaturation situation, there is some one-to-one correspondence between the Q factor of resonator and the oscillation power of the oscillator. Therefore, FIGS. 18A and 18B confirms that gain optimization of the oscillator may be required to build one-to-one relationship between the Q factor of the resonator and the oscillator power of the oscillator.

However, FIG. 18B shows that the oscillator stops oscillating at extreme resonator loss conditions, such as 55% WC (1802b) and 78% GVF. This is due to reducing the dynamic range of the resonator losses that can satisfy the gain condition of the oscillator. Put differently, at the extreme loss conditions the oscillator gain is not sufficient for sustained oscillations. Accordingly, even though optimizing (reducing) the oscillator gain provides one-to-one correspondence between the Q factor of the resonator and the oscillation power of the oscillator, the dynamic range of the one-to-one correspondence may become smaller.

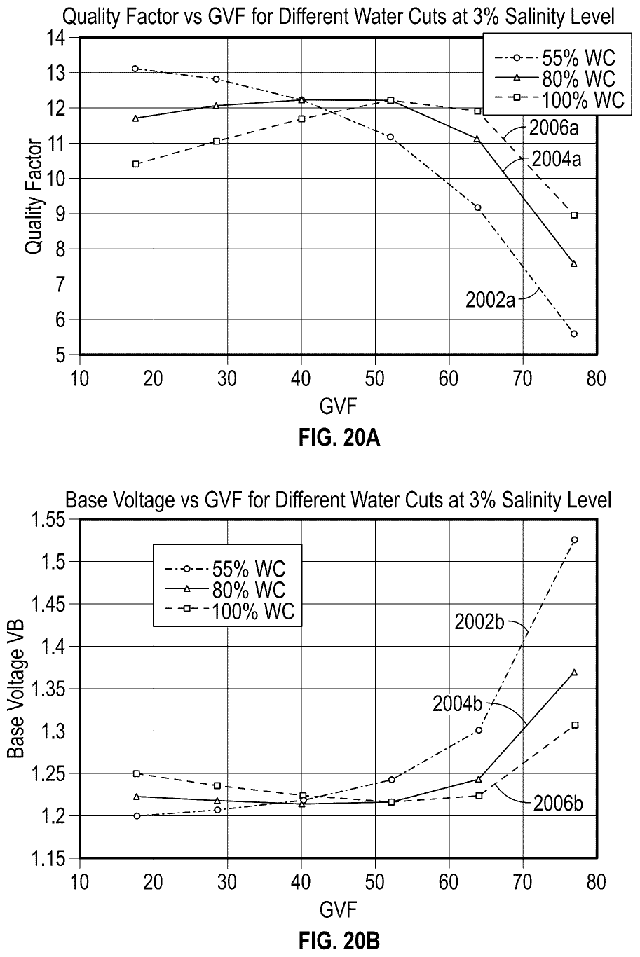

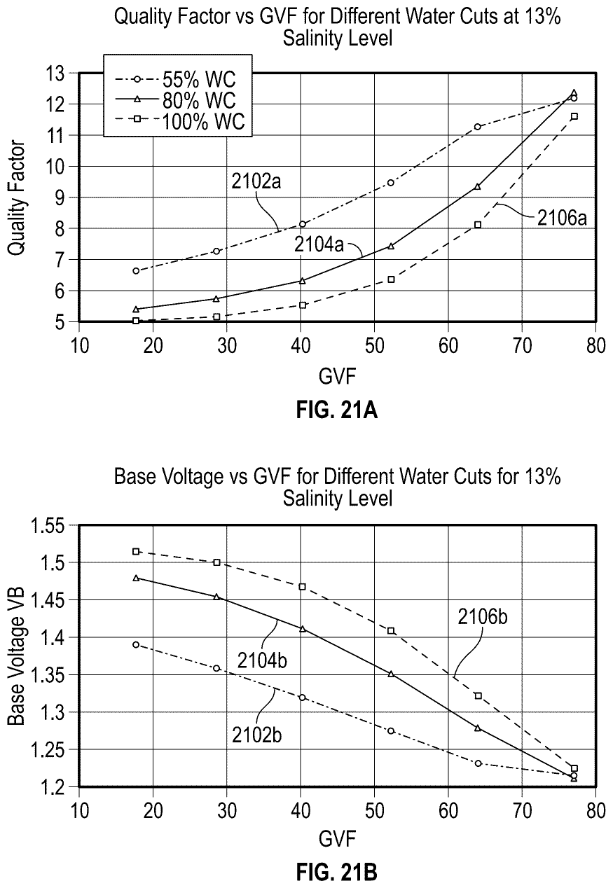

One or more embodiments described herein provide another method for measuring the Q factor of the resonator that may be done in a wider dynamic range. Specifically, a dynamic gain adjustment method controlled through a base voltage (Vb) of the oscillator is described herein. FIG. 19 shows the oscillator gain as a function of frequency for different magnitudes of the Vb of the oscillator. m1 and m10 in FIG. 19 show the oscillator gain at frequencies of 130.3 MHz and 139.9 MHz, respectively, for different magnitudes of the Vb. As shown in FIG. 19, the oscillator gain can be controlled/adjusted by changing the Vb of the oscillator. Using this approach, the Q factor of the resonator and the simulated required Vb of the oscillator, at low salinity of 3% for the medium under measurement, are mapped in FIG. 20 in relation with WC and GVF. “Required” Vb is the voltage which is required just to make the oscillator oscillate at a fixed output power level, for example 0 dBm (1 mW). Specifically, FIG. 20 shows, on the left side, the Q factor for WCs of 55% (2002a), 80% (2004a), and 100% (2006a). FIG. 20 also shows, on the right side, the Vb for WCs of 55% (2002b), 80% (2004b), and 100% (2006b). As shown in FIG. 20, the Vb follows the same trend (but inverted) as the Q factor of the resonator. Thus, the Q factor of the resonator, which corresponds to the dielectric loss of the medium subject to measurement, has one-to-one relationship with the Vb of the oscillator in a wide dynamic range. Accordingly, the Q factor of the resonator and the dielectric losses of the medium can be measured through measuring the Vb of the oscillator.

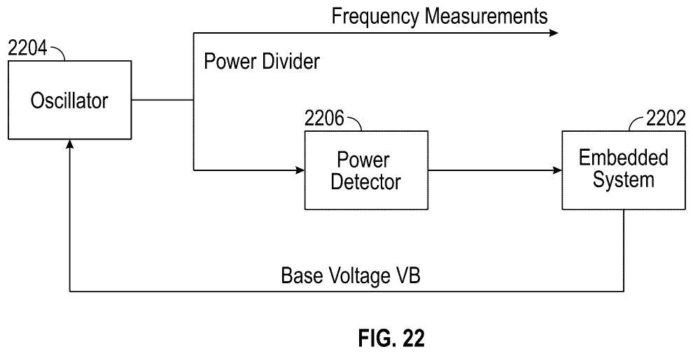

FIG. 21 shows the Q factor of the resonator and the required Vb of the oscillator, at higher salinity of 13% for the medium under measurement, in relation with WC and GVF. Specifically, FIG. 21 shows, on the left side, the Q factor for WCs of 55% (2102a), 80% (2104a), and 100% (2106a). FIG. 21 also shows, on the right side, the Vb for WCs of 55% (2102b), 80% (2104b), and 100% (2106b). As shown in FIG. 21, even at higher salinity there is good one-to-one correspondence between the Q factor of the resonator and the Vb of the oscillator. Accordingly, the Q factor of the resonator and the dielectric losses of the medium can be measured through measuring the Vb of the oscillator even at higher salinity.

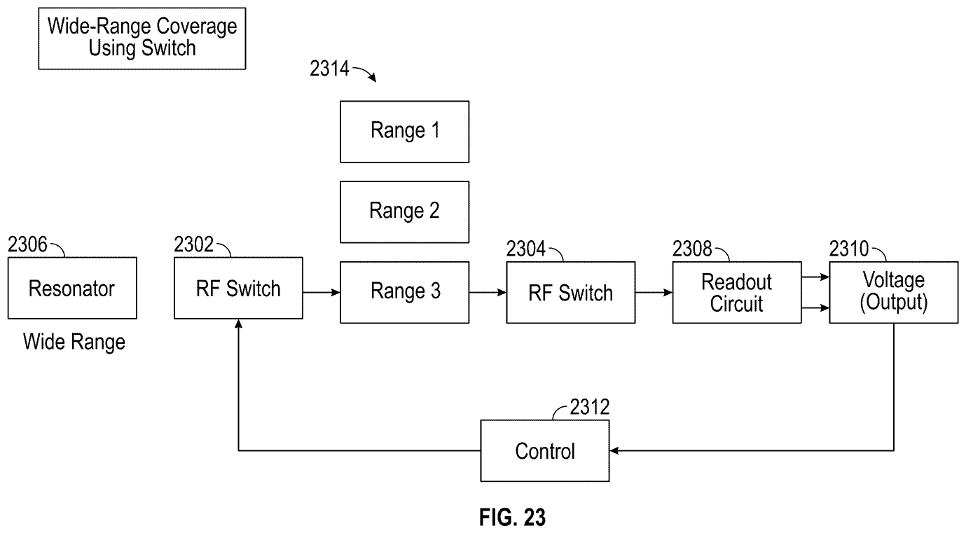

FIG. 22 shows a block diagram for controlling the Vb of the oscillator. Specifically, the embedded system (2202), which is an electronic system that can control its output voltage or current, controls the Vb of the oscillator (2204). Then, the signal output of the oscillator is split via the power divider. One line of the split signal output of the oscillator goes into a power detector to measure the gain of the oscillator. The measured gain of the oscillator is then fed back to the embedded system for adjustment/control of the Vb by the embedded system. Another line of the split signal output of the oscillator goes into a device (e.g., spectrometer) that can measure the oscillation frequency of the oscillator.

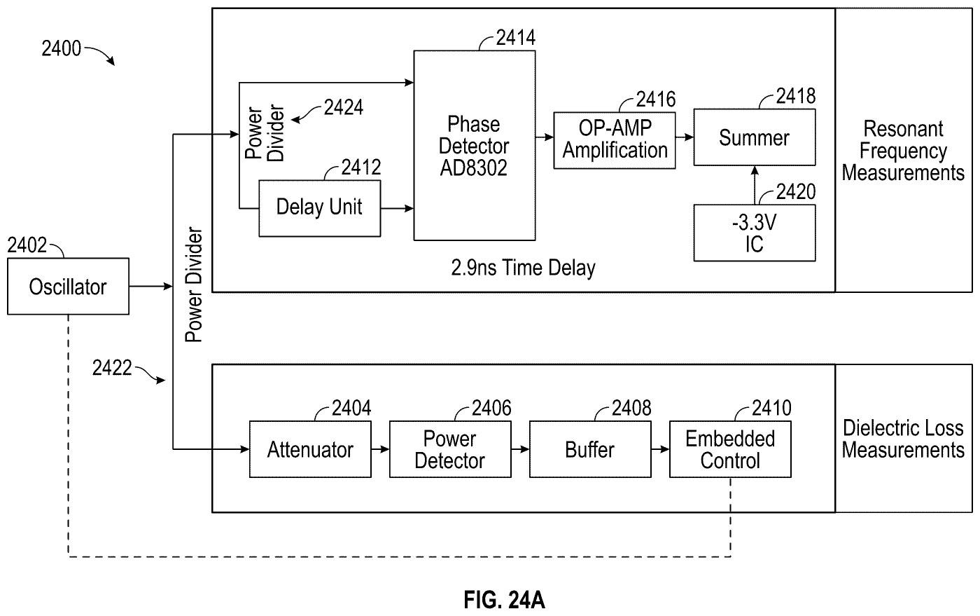

According to one or more embodiments, to further increase the frequency coverage range of the measurements, radio frequency (RF) sensor(s) may be used in the readout circuitry. FIG. 23 shows an example of the readout circuitry system including two RF switches that can extend the coverage range of reading into range 3. Specifically, Ranges 1-3 denote three different oscillators that function in respectively different ranges. For example, Ranges 1-3 may denote oscillators 1-3 that respectively operate in frequency ranges 130-160 MHz, 160-190 MHz, and 190-220 MHz. The first RF switch (2302) connects the resonator (2306) to the appropriate oscillator (2314), and the second RF switch (2304) connects the output of the active (chosen) oscillator (2314), which depends on the operation range, to the readout circuitry (2308). Accordingly, a wideband frequency range is achieved. The number of the oscillators (number of Ranges) may not be limited to three and can vary depending on the wanted bandwidth of the operation.

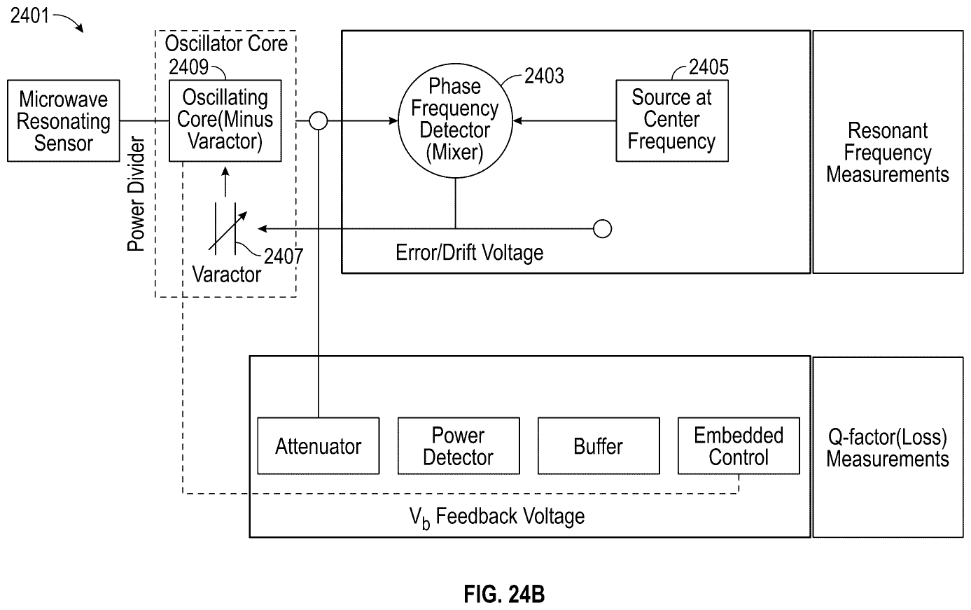

FIG. 24A shows Architecture 1 of the overall readout circuitry (2400) by which the resonance frequency of the resonator, which represents the dielectric constant of the medium, and the Q factor of the resonator, which represents the dielectric losses of the medium, can be measured. Accordingly to one or more embodiments, the two measurements can be performed simultaneously. Specifically, the readout circuitry (2400) can measure the resonance frequency of the resonator and dielectric losses of the medium through measuring the output of the oscillator (2402). To this end, the oscillator signal goes into a first power divider (2422) to split the signal into two routes, one for measuring the resonance frequency and the other one for measuring the dielectric losses of the medium, which may be performed simultaneously. The signal line that is routed for measuring the dielectric losses goes into an attenuator (2404) to reduce the amplitude of the signal, then into a power detector to measure the signal power and thereby measure the oscillation power of the oscillator (2402), then into a buffer (2408) that buffers the signal before going into an embedded control (2410) where the Vb of the oscillator can be measured. As described above with reference to FIGS. 18A to 21, the dielectric losses of the medium can be determined by measuring the Q factor of the resonator, which itself can be determined by measuring the oscillation power of the oscillator or the Vb.

The other line of the signal after the first power divider (2422) that is used for measuring the resonance frequency of the resonator goes into a second power divider (2424). The second power divider (2424) splits the signal into two lines of signal where one goes directly into a phase detector (2414) and the other one goes into a delay unit (2412) before going into the phase detector (2414). The delay unit (2412) delays the signal by a certain time, for example 2.9 nanosecond. The phase detector (2414) detects the phase difference between the two incoming lines and outputs a DC voltage directly related with the phase difference. This phase difference is directly related with the oscillation frequency of the oscillator (2402). Hence, the DC voltage out of phase detector (2414) is directly linked with the oscillation frequency. The output of the phase detector (2414) goes into an operational amplifier (OP-AMP) (2416) and then to a summer (adder) (2418). The OP-AMP (2416) amplifies the DC voltage to increase the sensitivity, to detect even small changes in DC voltages or in other words small changes in oscillation frequency. The summer (2418) with the −3.3V IC (2420) give an offset to the DC voltage coming from phase detector (2414). This is to make the signal closer to 0V, to reduce voltages in the circuit. Thereby, the circuitry will become more power efficient and may require less high-dynamic-range electronic components.

FIG. 24B shows Architecture 2 (which is different from Architecture 1) of the overall readout circuitry (2401) in which the loss measurements are performed using an RF power detector, for example similar to the one for Architecture 1 (2400). However, in Architecture 2 (2401), the resonance frequency measurements are performed differently from the resonance frequency measurements of Architecture 1 (2400). Specifically, in Architecture 2 (2401), a circuit (e.g. a mixer (2403)) measures the drift in frequency with respect to a fixed center frequency that is from a source operating at the center frequency (2405). The drift, which may be an error voltage, tunes a varactor (2407) to make the oscillator (i.e., oscillator core) (2409) to oscillate at the center frequency. A higher error voltage would mean a higher drift from the center frequency, which is an indication of the oscillation frequency of the oscillator. The drift or error voltage indicates the resonance frequency of the resonator.

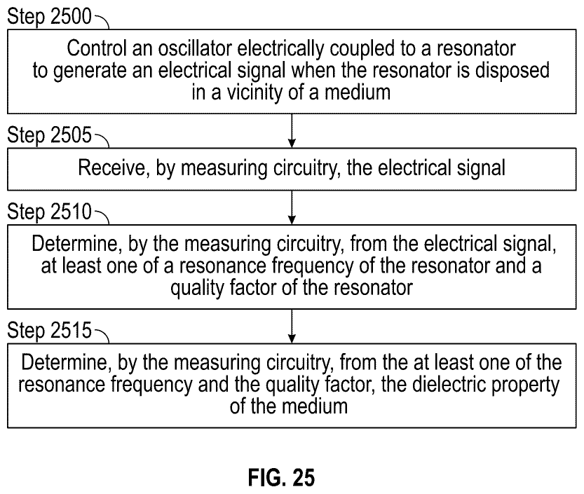

FIG. 25 shows a flowchart for measuring dielectric properties of a medium at high frequencies, such as microwave frequencies, in accordance with one or more embodiments. In one or more embodiments, one or more of the steps shown in FIG. 25 may be omitted, repeated, and/or performed in a different order than the order shown in FIG. 25. Accordingly, the scope of the invention should not be considered limited to the specific arrangement of the steps shown in FIG. 25. The steps shown in FIG. 25 are explained below.

Step 2500 includes controlling on an oscillator electrically coupled to a resonator to generate an electrical signal in an oscillation frequency when the resonator is disposed in a vicinity of the medium. For example, the oscillator may be electrically powered to provide the oscillation gain that feeds the resonator. Some examples of this step are described above with reference to FIGS. 2 and 3. The resonator is disposed in the vicinity of the medium such that the microwave radiation of the resonator enters the medium and changes the resonance frequency of the resonator by a detectable fraction. For example, the resonator may be disposed in or on the medium, may contain the medium, or may be disposed adjacent to the medium without contacting the medium, depending on measurement sensitivity, situation, or other factors.

In Step 2505, measuring circuitry receives the electrical signal. Some examples of this step are described above with reference to FIGS. 9 and 22-24B.

In Step 2510, the measuring circuitry determines, from the electrical signal, at least one of a resonance frequency of the resonator and a Q factor of the resonator. For example, the measuring circuitry determines the at least one of the resonance frequency and Q factor of the resonator based on one-to-one correspondence between the electrical signal of the oscillator and the at least one of the resonance frequency and Q factor of the resonator. Some examples of this step are described above with reference to FIGS. 10-13, 18A, 18B, 20, and 21.

In Step 2515, the measuring circuitry determines, from the at least one of the resonance frequency and Q factor of the resonator, the dielectric property of the medium. For example, the measuring circuitry determines the dielectric property of the medium based on one-to-one correspondence between the dielectric property of the medium and the at least one of the resonance frequency and Q factor of the resonator. For example, the dielectric property of the medium may be the dielectric constant of the medium at microwave frequencies, which can be determined based on one-to-one correspondence to the resonance frequency of the resonator. Or the dielectric property of the medium may be the dielectric loss of the medium at microwave frequencies, which can be determined based on one-to-one correspondence to the Q factor of the resonator. The one-to-one correspondences may be in one or more tables, which may be used to find the dielectric property from the measured resonance frequency or Q factor of the resonator or from oscillation power, phase, oscillation frequency, or Vb of the oscillator.

The method may further include one or more steps based on the embodiments described above. Some examples of these steps are as follows.

In one or more embodiments, the measuring circuitry may determine, from the electrical signal, the resonance frequency of the resonator based on an intersection of a phase of the resonator with an inverted phase of the oscillator.

In one or more embodiments, the measuring circuitry may determine, from the electrical signal, the resonance frequency of the resonator based on an oscillation frequency of the oscillator.

In one or more embodiments, the measuring circuitry may determine, from the electrical signal, the Q factor of the resonator based on a power of the oscillator. As described above, the measuring circuitry may determine the power of the oscillator in a state where the oscillator is not saturated.

In one or more embodiments, the measuring circuitry may determine, based on the electrical signal, the Q factor of the resonator based on the Vb of the oscillator. In one or more embodiments, the measuring circuitry may use the Vb to control the gain of the oscillator.

In one or more embodiments, the measuring circuitry determines the dielectric constant (i.e., a dielectric property) of the medium in microwave frequencies, based on the resonance frequency of the resonator. In addition, the measuring circuitry may determine the dielectric loss (i.e., another dielectric property) of the medium in microwave frequencies, based on the Q factor of the resonator.

In one or more embodiments, the system may determine, from the measured dielectric property of the medium, the WC or GVF of the medium.

In one or more embodiments, while the measuring circuitry reads the electrical signal of the oscillator, an operating gain of the oscillator is controlled to be greater than an operating loss of the resonator and the sum of an operating phase of the oscillator and an operating phase of the resonator is controlled to be 0°.

In one or more embodiments, the measuring circuitry may control an operating frequency range of the oscillator for generating the electrical signal of the oscillator, via two capacitors.

The microwave dielectric sensor (i.e., the microwave readout circuitry) described in the above embodiments are advantageous compared to conventional dielectric sensors. More than 50% of MPFMs employ dielectric measurements. The reason for popularity of dielectric sensors is that they are safe and non-intrusive to the measuring medium. However, dielectric measurements performed at low frequencies are prone to effect of phase inversion (oil continuous to water continuous and vice versa) and may require physical contact with the fluid (e.g., being flushed into the tube wall), for example for conductivity measurements.

For this reason, dielectric measurements at high (microwave) frequencies are becoming more popular because microwaves can work over the full range of WC (oil and water continuous) and can penetrate through dielectric medium. That is why they do not require physical contact with the fluid inside the pipeline. Despite these advantages, one of the downside with microwave sensing is that conventional microwave readout circuitry at high speed is not commonly available OTS. One or more embodiments described herein present a novel readout circuitry to not only convert the microwave resonance into microwave oscillation but also to convert it into corresponding voltage, which can easily be read through an embedded system. The readout circuitry according to one or more embodiments is capable of simultaneously measuring the resonance frequency as well as the dielectric loss of the multiphase medium.

Another feature of the readout circuitry, in accordance with one or more embodiments, is that it has wide dynamic range to measure the dielectric loss of the multiphase medium. This is especially may be helpful because the water in the medium may have content with a widely different salinity. For example, the water may have dissolved salts anywhere between 1,000 parts per million (ppm) to 250,000 ppm and the salts affect the dielectric loss of the water. Due to such large variation, in one oil and gas example, the dielectric loss of the multiphase water may vary significantly from one oil and gas field to another. Therefore, the wide dynamic range of the readout circuitry in accordance with one or more embodiments to measure the dielectric loss may be advantageous. In addition, in the above embodiments the concept of loss dependent gain voltage of the oscillator, which dynamically adjusts the oscillator based on the dielectric loss of the medium, was introduced. This approach makes it possible to measure widely different values of dielectric losses.

The followings are some of the distinguishing features of the readout circuitry for the microwave resonator-based sensor, in accordance with one or more embodiments described above:
simultaneously relate the output voltage of the oscillator to the resonance frequency of the resonator as well as the dielectric losses;
a wide dynamic range to measure the dielectric losses; and
being compact, fast, and power efficient.

The fast response of the readout circuit opens new possibility to correlate the response of multiple resonators (such as two resonators in the DMOR technology) to determine additional information about the multiphase medium such as GVF or the gas/liquid flow rates.

One or more embodiments disclosed herein for measuring the dielectric properties of the medium, for example with reference to FIGS. 9 and 18A-25, may be implemented on virtually any type of computer system, regardless of the platform being used. The computer system may have programs or algorithms to control the functions/operations of the measurement described in the above embodiments. For example, the computer system may be one or more mobile devices (e.g., laptop computer, smart phone, personal digital assistant, tablet computer, or other mobile device), desktop computers, servers, blades in a server chassis, or any other type of computer system that includes at least the minimum processing power, memory, and input and output device(s) to perform one or more embodiments of the invention.

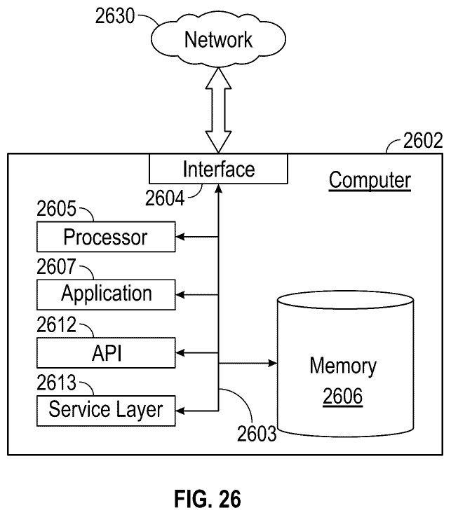

An example of the computer system is described with reference to FIG. 26, in accordance with one or more embodiments. FIG. 26 is a block diagram of a computer system used to provide computational functionalities associated with described algorithms, methods, functions, processes, flows, and procedures as described in the instant disclosure, according to an implementation. The illustrated computer (2602) in the computer system is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (2602) may include an input device, such as a keypad, keyboard, touch screen, or other device that can accept user information, and an output device that conveys information associated with the operation of the computer (2602), including digital data, visual, or audio information (or a combination of information), or a GUI.

In one or more embodiments, the measuring circuitry described in the above embodiments may include the computer (2602), may be in the form of the computer (2602), or may be coupled to the computer (2602) such that the computer (2602) analyzes the measured signal by the measuring circuitry. For example, the measuring circuitry may include the computer (2602) in addition to circuitry used to measure the electrical signal of the oscillator. In one or more embodiments, the measuring circuitry may also include a VNA, which may measure the signal of the resonator. For example, the measuring circuitry may include the VNA to measure the resonance frequency of the resonator through measuring the phases and phase intersections as described above for example with respect to FIGS. 10-12. In other embodiments, however, the measuring circuitry may be separate circuitry from the VNA.

The computer (2602) can serve in a role as a client, network component, a server, a database or other persistency, or any other component (or a combination of roles) of a computer system for performing the subject matter described in the instant disclosure. The illustrated computer (2602) is communicably coupled with a network (2630). In some implementations, one or more components of the computer (2602) may be configured to operate within environments, including cloud-computing-based, local, global, or other environment (or a combination of environments).

At a high level, the computer (2602) is an electronic computing device operable to receive, transmit, process, store, or manage data and information associated with the described subject matter. According to some implementations, the computer (2602) may also include or be communicably coupled with an application server, e-mail server, web server, caching server, streaming data server, business intelligence (BI) server, or other server (or a combination of servers).

The computer (2602) can receive requests over network (2630) from a client application (for example, executing on another computer (2602)) and responding to the received requests by processing the said requests in an appropriate software application. In addition, requests may also be sent to the computer (2602) from internal users (for example, from a command console or by other appropriate access method), external or third-parties, other automated applications, as well as any other appropriate entities, individuals, systems, or computers.

Each of the components of the computer (2602) can communicate using a system bus (2603). In some implementations, any or all of the components of the computer (2602), both hardware or software (or a combination of hardware and software), may interface with each other or the interface (2604) (or a combination of both) over the system bus (2603) using an application programming interface (API) (2612) or a service layer (2613) (or a combination of the API (2612) and service layer (2613)). The API (2612) may include specifications for routines, data structures, and object classes. The API (2612) may be either computer-language independent or dependent and refer to a complete interface, a single function, or even a set of APIs. The service layer (2613) provides software services to the computer (2602) or other components (whether or not illustrated) that are communicably coupled to the computer (2602). The functionality of the computer (2602) may be accessible for all service consumers using this service layer (2613). Software services, such as those provided by the service layer (2613), provide reusable, defined business functionalities through a defined interface. For example, the interface may be software written in JAVA, C++, Python, or other suitable language providing data in extensible markup language (XML) format or another suitable format. While illustrated as an integrated component of the computer (2602), alternative implementations may illustrate the API (2612) or the service layer (2613) as stand-alone components in relation to other components of the computer (2602) or other components (whether or not illustrated) that are communicably coupled to the computer (2602). Moreover, any or all parts of the API (2612) or the service layer (2613) may be implemented as child or sub-modules of another software module, enterprise application, or hardware module without departing from the scope of this disclosure.

The computer (2602) includes an interface (2604). Although illustrated as a single interface (2604) in FIG. 26, two or more interfaces (2604) may be used according to particular needs, desires, or particular implementations of the computer (2602). The interface (2604) is used by the computer (2602) for communicating with other systems in a distributed environment that are connected to the network (2630). Generally, the interface (2604) includes logic encoded in software or hardware (or a combination of software and hardware) and operable to communicate with the network (2630). More specifically, the interface (2604) may include software supporting one or more communication protocols associated with communications such that the network (2630) or interface's hardware is operable to communicate physical signals within and outside of the illustrated computer (2602).

The computer (2602) includes at least one computer processor (2605). Although illustrated as a single computer processor (2605) in FIG. 26, two or more processors may be used according to particular needs, desires, or particular implementations of the computer (2602). Generally, the computer processor (2605) executes instructions and manipulates data to perform the operations of the computer (2602) and any algorithms, methods, functions, processes, flows, and procedures as described in the instant disclosure.

The computer (2602) also includes a memory (2606) that holds data for the computer (2602) or other components (or a combination of both) that can be connected to the network (2630). For example, memory (2606) can be a database storing data consistent with this disclosure. In one example, memory (2606) may store programs or algorithms for controlling operation of the readout circuitry that is described in the above embodiments. More specifically, in this example, the programs or algorithms may control operation of the oscillator or circuitry and may control to read the signal output of the oscillator (e.g., the oscillation frequency, phase, or base voltage of the oscillator) described above in accordance with one or more embodiments. In another example, the memory may store tables that include the one-to-one relationships/correspondences described in the above embodiments, such as the one-to-one correspondences between the oscillation frequencies and the resonance frequencies, between the phase meeting/matching points and the resonance frequencies, between the oscillation powers and the Q factors, between the base voltages and the Q factors, between the resonance frequencies and the dielectric constants of the medium, between the Q factors and the dielectric losses of the medium, or any combination therefrom. Although illustrated as a single memory (2606) in FIG. 26, two or more memories may be used according to particular needs, desires, or particular implementations of the computer (2602) and the described functionality. While memory (2606) is illustrated as an integral component of the computer (2602), in alternative implementations, memory (2606) can be external to the computer (2602).

The application (2607) is an algorithmic software engine providing functionality according to particular needs, desires, or particular implementations of the computer (2602), particularly with respect to functionality described in this disclosure. For example, the application (2607) can serve as one or more components, modules, applications, etc. In one example, the application (2607) may include programs or algorithms for controlling operation of the readout circuitry that is described in the above embodiments. More specifically, in this example, the programs or algorithms may control operation of the oscillator or circuitry and may control to read the signal output of the oscillator (e.g., the oscillation frequency, phase, or base voltage of the oscillator) described above in accordance with one or more embodiments. In another example, the memory may store tables that include the one-to-one relationships/correspondences described in the above embodiments, such as the one-to-one correspondences between the oscillation frequencies and the resonance frequencies, between the phase meeting/matching points and the resonance frequencies, between the oscillation powers and the Q factors, between the base voltages and the Q factors, between the resonance frequencies and the dielectric constants of the medium, between the Q factors and the dielectric losses of the medium, or any combination therefrom. Further, although illustrated as a single application (2607), the application (2607) may be implemented as multiple applications (2607) on the computer (2602). In addition, although illustrated as integral to the computer (2602), in alternative implementations, the application (2607) can be external to the computer (2602). In one example, the method described with reference to FIG. 25 may be implemented by the application (2607).

There may be any number of computers (2602) associated with, or external to, a computer system containing computer (2602), each computer (2602) communicating over network (2630). Further, the term “client,” “user,” and other appropriate terminology may be used interchangeably as appropriate without departing from the scope of this disclosure. Moreover, this disclosure contemplates that many users may use one computer (2602), or that one user may use multiple computers (2602). Furthermore, in one or more embodiments, the computer (2602) is a non-transitory computer readable medium (CRM).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A system for measuring a dielectric property of a medium, the system comprising:
a resonator;
an oscillator electrically coupled to the resonator and configured to generate an electrical signal representing an oscillation of the oscillator when the resonator is disposed in a vicinity of the medium; and
measuring circuitry that receives the electrical signal,
wherein the measuring circuitry determines, from the electrical signal, at least one of a resonance frequency of the resonator and a quality factor of the resonator, and
wherein the measuring circuitry determines, from the at least one of the resonance frequency and the quality factor, the dielectric property of the medium.

2. The system of claim 1, wherein
the measuring circuitry comprises a vector network analyzer (VNA),
the measuring circuitry determines, from the electrical signal, the resonance frequency of the resonator, and
the measuring circuitry determines the resonance frequency of the resonator, from the electrical signal, using the VNA to measure an intersection of a phase of the resonator with an inverted phase of the oscillator.

3. The system of claim 1, wherein
the measuring circuitry determines, from the electrical signal, the resonance frequency of the resonator, and
the measuring circuitry determines, from the electrical signal, the resonance frequency of the resonator based on an oscillation frequency of the oscillator.

4. The system of claim 1, wherein
the measuring circuitry determines, from the electrical signal, the quality factor of the resonator, and
the measuring circuitry determines, from the electrical signal, the quality factor of the resonator based on a power of the oscillator.

5. The system of claim 4, wherein the measuring circuitry determines the power of the oscillator in a state where the oscillator is not saturated.

6. The system of claim 1, wherein
the measuring circuitry determines, based on the electrical signal, the quality factor of the resonator, and
the measuring circuitry determines, based on the electrical signal, the quality factor of the resonator based on a base voltage of the oscillator.

7. The system of claim 6, wherein the measuring circuitry uses the base voltage to control a gain of the oscillator.

8. The system of claim 1,
wherein the system comprises a coaxial cable that connects the resonator to the oscillator, and
wherein a length of the coaxial cable is not more than 6 inches.

9. The system of claim 1, wherein the resonator is directly connected to the oscillator without using a coaxial cable.

10. The system of claim 1, wherein the oscillator is a Colpitts oscillator.

11. The system of claim 1, wherein the measuring circuitry determines the dielectric property of the medium in microwave frequencies.

12. The system of claim 1, wherein the system determines, from the dielectric property of the medium, a Water-Cut of the medium.

13. The system of claim 1, wherein the system determines, from the dielectric property of the medium, a Gas Volume Fraction of the medium.

14. The system of claim 1,
wherein the oscillator stabilizes the electrical signal in less than 500 nanosecond (ns), and
wherein the measuring circuitry determines the at least one of the resonance frequency and the quality factor in less than 0.5 millisecond (ms).

15. The system of claim 1, wherein the resonator is a T-resonator.

16. The system of claim 1, wherein the system further comprises at least one Radio Frequency (RF) switch that feeds the electrical signal to the measuring circuitry.

17. The system of claim 1, wherein, the measuring circuitry determines the dielectric property of the medium in a state where
an operating gain of the oscillator is greater than an operating loss of the resonator and
the sum of an operating phase of the oscillator and an operating phase of the resonator is 0°.

18. The system of claim 1, wherein the oscillator comprises two capacitors that control an operating frequency range of the oscillator for generating the electrical signal.

19. A method for measuring a dielectric property of a medium, the method comprising:
controlling an oscillator electrically coupled to a resonator to generate an electrical signal representing an oscillation of the oscillator when the resonator is disposed in a vicinity of the medium;
receiving, by measuring circuitry, the electrical signal;
determining, by the measuring circuitry, from the electrical signal, at least one of a resonance frequency of the resonator and a quality factor of the resonator; and
determining, by the measuring circuitry, from the at least one of the resonance frequency and the quality factor, the dielectric property of the medium.

20. A non-transitory computer readable medium (CRM) storing instructions for performing an operation that measures a dielectric property of a medium, the operation comprising:
controlling an oscillator electrically coupled to a resonator to generate an electrical signal representing an oscillation of the oscillator when the resonator is disposed in a vicinity of the medium;
receiving, by measuring circuitry, the electrical signal;
determining, by the measuring circuitry, from the electrical signal, at least one of a resonance frequency of the resonator and a quality factor of the resonator; and
determining, by the measuring circuitry, from the at least one of the resonance frequency and the quality factor, the dielectric property of the medium.
